(19) United States
(12) Patent Application Publication
(10) Pub. No.: US 2018/0277338 A1
(43) Pub. Date: Sep. 27, 2018

(54) PLASMA GENERATION METHOD, PLASMA PROCESSING METHOD USING THE SAME AND PLASMA PROCESSING APPARATUS

(71) Applicant: Tokyo Electron Limited, Tokyo (JP)

(72) Inventors: Takehiro FUKADA, Iwate (JP); Takashi CHIBA, Iwate (JP)

(21) Appl. No.: 15/933,896

(22) Filed: Mar. 23, 2018

(30) Foreign Application Priority Data
Mar. 27, 2017 (JP) 2017-060556

(51) Int. Cl. H01J 37/32; C23C 16/455; C23C 16/52

(52) U.S. Cl. CPC H01J 37/32137; C23C 16/45536; C23C 16/45544; H01J 2237/3321; C23C 16/52; H01J 2237/327; C23C 16/45563

(57) ABSTRACT

A plasma generation method is provided to generate and maintain plasma by supplying a predetermined power that is lower than a normal power to a plasma generator. Plasma of an ignition gas is generated by supplying the normal power to the plasma generator. A power input to the plasma generator is decreased by a first power that is smaller than a difference between the normal power and the predetermined power. The power input to the plasma generator is decreased by a second power that is smaller than the first power. Decreasing the power input to the plasma generator by the second power is performed after decreasing the power input to the plasma generator by the first power and is repeated a plurality of times.

### CROSS-REFERENCE TO RELATED APPLICATION

The present application is based upon and claims the benefit of priority of Japanese Patent Application No. 2017-060556, filed on Mar. 27, 2017, the entire contents of which are incorporated herein by reference.

### BACKGROUND OF THE INVENTION

### 1. Field of the Invention

The present invention relates to a plasma generation method, a plasma processing method using the same and a plasma processing apparatus.

### 2. Description of the Related Art

Japanese Laid-Open Patent Application Publication No. 2015-154025 discloses a method for operating a plasma processing apparatus that generates plasma by supplying a first radio frequency power having a predetermined output to an electrode and processes an object with the plasma. In the method, when a period of time from the end of previous operation of the plasma processing apparatus exceeds a predetermined period of time, the plasma processing apparatus starts a plasma process after performing a charge accumulation process of supplying a second radio frequency power having a smaller output than the predetermined output to the electrode.

The technique disclosed in Japanese Laid-Open Patent Application Publication No 2015-154025 introduces an ignition sequence that facilitates the ignition of plasma after a stop for a long period of time because the ignition of plasma is likely to be difficult when the plasma processing apparatus is stopped for a long period of time for maintenance and the like.

However, although Japanese Laid-Open Patent Application Publication No 2015-154025 discloses the sequence that facilitates the ignition of plasma after the stop for a long period of time, Japanese Laid-Open Patent Application Publication No 2015-154025 fails to disclose a technique for maintaining plasma without extinguishing the plasma when the output of plasma is lowered.

In the meantime, film deposition processes in recent years includes a process of depositing a silicon oxide film on a wafer on which a silicon nitride film is formed as an undercoat film. In such a film deposition of the silicon oxide film, an oxidation gas is sometimes supplied to a wafer while being converted to plasma to oxidize a silicon-containing gas and to modify a deposited silicon oxide film. However, such oxidizing plasma may oxidize the silicon nitride film used as the undercoat film. To prevent the oxidation of the undercoat film, measures of decreasing power supplied to a plasma generator and thereby decreasing intensity of plasma are considered. However, performing the measures sometimes causes a problem of extinguishing the plasma. Usually, plasma generators are configured to generate plasma when predetermined power is supplied. Hence, even if the plasma is generated once by supplying the usual power to the plasma generator, when the supplied power is lowered to decrease the intensity of plasma after the generation, the plasma is sometimes extinguished, and the plasma having low power cannot be generated.

### SUMMARY OF THE INVENTION

Embodiments of the present disclosure provide a plasma generation method and plasma processing method using the same, and a plasma processing apparatus solving one or more of the problems discussed above.

More specifically, the embodiments of the present disclosure may provide a plasma generation method and plasma processing method using the same, and a plasma processing apparatus that can generate plasma having energy lower than usual plasma and stably maintaining the plasma even when a usual plasma generator is used.

According to an embodiment of the present invention, there is provided a plasma generation method to generate and maintain plasma by supplying a predetermined power that is lower than a normal power to a plasma generator. Plasma of an ignition gas is generated by supplying the normal power to the plasma generator. A power input to the plasma generator is decreased by a first power that is smaller than a difference between the normal power and the predetermined power. The power input to the plasma generator is decreased by a second power that is smaller than the first power. Decreasing the power input to the plasma generator by the second power is performed after decreasing the power input to the plasma generator by the first power and is repeated a plurality of times.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a sequence diagram illustrating an example of a plasma generation method according to an embodiment of the present disclosure;

FIG. 2 is a diagram illustrating a conventional sequence of a comparative example;

FIG. 3 is a diagram illustrating a state of plasma in a conventional sequence of a comparative example;

FIG. 4 is a diagram illustrating a state of plasma of a plasma generation method according to an embodiment of the present disclosure;

FIG. 5 is a diagram illustrating an example of a plasma generation method according to an embodiment of the present disclosure;

FIG. 6 is a schematic vertical cross-sectional view illustrating a plasma processing apparatus of an example according to an embodiment of the present disclosure;

FIG. 7 is a schematic plan view illustrating a plasma processing apparatus of an example according to an embodiment of the present disclosure;

FIG. 8 is a cross-sectional view of a part of a plasma processing apparatus taken along a concentric circle of a susceptor;

FIG. 9 is a vertical cross-sectional view of an example of a plasma generator of a plasma processing apparatus according to an embodiment of the present disclosure;

FIG. 10 is an exploded perspective view of an example of a plasma generator of a plasma processing apparatus according to an embodiment of the present disclosure;

FIG. 11 is a perspective view of an example of a housing of a plasma generator of a plasma processing apparatus according to an embodiment of the present disclosure;

FIG. 12 is a vertical cross-sectional view of a vacuum chamber taken along a rotational direction of a susceptor of a plasma processing apparatus according to an embodiment of the present disclosure;

FIG. 13 is an enlarged perspective view of a plasma process gas nozzle provided in a plasma process region of a plasma processing apparatus according to an embodiment of the present disclosure;

FIG. 14 is a plan view of an example of a plasma generator of a plasma processing apparatus according to an embodiment of the present disclosure;

FIG. 15 is a perspective view illustrating a part of a Faraday shield provided in a plasma generator of a plasma processing apparatus according to an embodiment of the present disclosure; and

FIG. 16 is a diagram showing an experimental result of a plasma processing method of a working example.

### DESCRIPTION OF THE PREFERRED EMBODIMENTS

Embodiments of the present disclosure are described below with reference to the accompanying drawings.

### First Embodiment

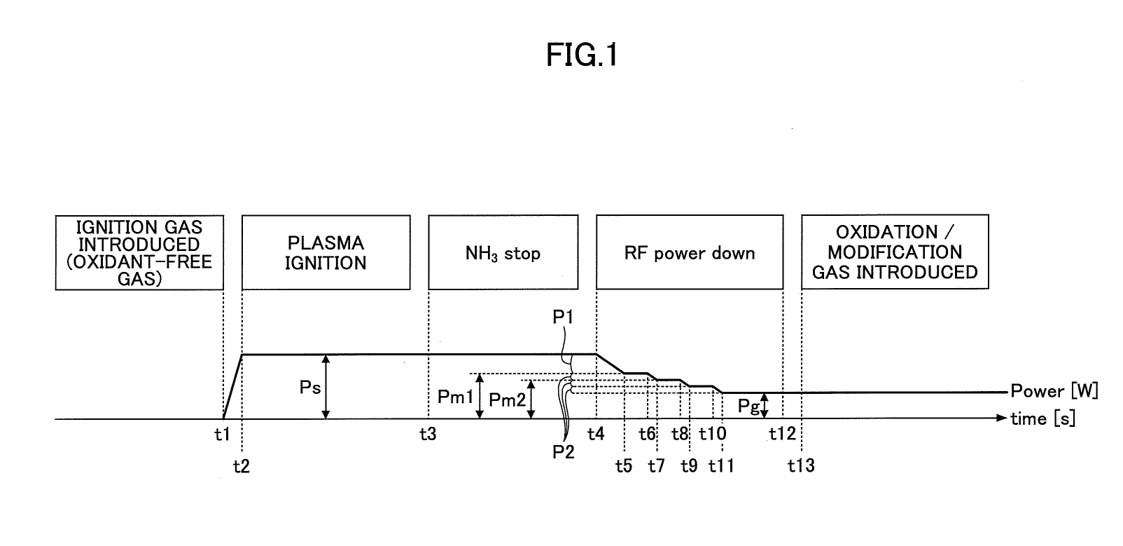

FIG. 1 is a sequence diagram illustrating an example of a plasma generation method according to a first embodiment of the present disclosure. In FIG. 1, a horizontal axis shows time [s], and a vertical axis shows output power [W] of a radio frequency power source supplied to a plasma generator. Although the plasma generator and the radio frequency power source are not illustrated in FIG. 1, a variety of plasma generators and radio frequency power sources can be used.

As illustrated in FIG. 1, an ignition gas is introduced at time t1. A gas other than an oxidation gas, that is, a gas that does not contain an oxygen atom, is selected as the ignition gas. For example, the ignition gas may be ammonia (NH₃) gas. In this embodiment, an example of using ammonia gas as the ignition gas is described below.

Here, the reason why a non-oxidation gas that does not contain the oxygen atom is selected as the ignition gas is because when a film other than an oxide film is formed on a wafer W made of silicon as the undercoat film, if an oxidation gas is converted to plasma, oxygen radicals oxidize the undercoat film and the undercoat film thins. The undercoat film may be, for example, a SiN film and the like. When the SiN film is formed on the wafer W as the undercoat film, if the oxidation gas is converted to plasma, the SiN film sometimes thins. Therefore, in the present embodiment, a gas that does not contain the oxygen atom is used as the ignition gas.

At time t2, plasma is ignited. More specifically, the radio frequency power source supplies radio frequency power at normal power Ps to the plasma generator. Thus, the plasma generator generates plasma by normal operation. That is, plasma is ignited. Here, for example, the normal power Ps is frequently set at a value of 1500 W, 2000 W or the like.

At time t3, the supply of ammonia is stopped. Because the plasma is ignited once, even when the supply of ammonia is stopped, the plasma is maintained due to remaining ammonia.

During a period from time t4 to time t5, the radio frequency power from the radio frequency power source is decreased by power P1. At this time, the power supplied to the plasma generator is decreased from the normal power Ps by the power P1 to intermediate power Pm1. The intermediate power Pm1 is set at a level that does not reliably extinguish the plasma even when the output power of the radio frequency power is directly lowered after the ignition. When the normal power Ps is set at 1500 W or 2000 W, for example, the intermediate power Pm1 is set at a value of 1000 W or higher. In a power decreasing process at an early stage, the input power can be decreased widely.

During a period from t5 to t6, the power supplied to the plasma generator is maintained at the intermediate power Pm1. When the input power is continuously and widely decreased, the plasma is liable to be extinguished. Hence, when the input power reaches the intermediate power Pm1 by being decreased from the normal power Ps by the power P1, stabilization of plasma is awaited while the input power is maintained at the intermediate power Pm1 for a while. Thus, a fluctuation in and an influence on the plasma having the lowered power can be reduced.

During a period from time t6 to time t7, the output of the radio frequency power source is decreased by power P2. The power P2 is set at a value lower than the power P1. For example, when the normal power Ps is 1500 W or 2000 W, the power P2 may be set at about 200 W. When the output is decreased to the power Pm2 that is lower than the above-mentioned intermediate power Pm1, if the power is decreased widely only one time, the plasma is liable to be extinguished. Hence, after the power reaches the intermediate power Pm1, the input power is decreased by a small amount of power.

During a period from time t7 to time t8, the power Pm2 is maintained without any change. Thus, the plasma can be stabilized.

During a period from time t8 to time t9, the output of the radio frequency power source is decreased by the power P2. As with the period from time t6 to time t7, the power is decreased by the power P2, which has a smaller decreasing range.

During a period from time t9 to time t10, the output of the radio frequency power source is maintained. Thus, the plasma can be stabilized.

During a period from time t10 to time t11, the output of radio frequency power source is decreased by the power P2. Thus, the input power to the plasma generator reaches lowered power Pg that is a target value. The lowered power Pg is set to the level that generates less intense plasma that does not thin the SiN film of the undercoat film. Hence, it can be said that the input power reaches to the lowered power Pg that does not cause problem of thinning the undercoat film even if an oxidation gas is introduced, without extinguishing the plasma.

During a period from time t11 to time t12, the input power is maintained at the lowered power Pg. Thus, the plasma can be stabilized.

Here, the periods from time t6 to time t7, from time t8 time t9, and from time t10 to time t11 provided to decrease the power of the radio frequency power source by the power P2 are set to the same period of time. Similarly, the periods from time t7 to time t8 and from time t9 to time t10 provided to wait for the plasma to stabilize after decreasing the power of the radio frequency power source by the power P2, are set to the same period of time.

In contrast, the period from time t4 to time t5 provided to decrease the power of the radio frequency power source by the power P1 does not have to equal the above-mentioned periods from time t6 to time t7, from time t8 to time t9, and from time t10 to time t11 provided to decrease the power of the radio frequency power source by the power P2. Also, the period from time t5 to time t6 provided to wait for the plasma to stabilize after decreasing the power of the radio frequency power source by the power P1 does not have to equal the above-mentioned periods from time t7 to time t8 and from time t9 to time t10 provided to wait for the plasma to stabilize after decreasing the power of the radio frequency power source by the power P2. However, all of the power decreasing periods may be set to the same period as each other without any problem, and all of the waiting periods may be also set to the same period as each other without any problem. These periods can be set at appropriate values (lengths of time) depending on the intended use.

At time t13, an oxidation gas is introduced. The oxidation gas is supplied to a wafer W while being converted to plasma by the plasma generator. The oxidation gas activated by the plasma is used to deposit an oxide film and contributes to a modification of the oxide film. On the other hand, the activated oxidation gas does not thin the SiN film that is the undercoat film because the activated oxidation gas has the lowered energy. Thus, the oxidation and modification processes can be performed without thinning the undercoat film.

In this manner, the plasma energy can be lowered without extinguishing the plasma by decreasing the input power to the plasma generator by a low decreasing amount of the power P2 a plurality of times.

Moreover, the power can quickly reach the target value of the lowered power Pg by decreasing the power by the power P1 having the greater decreasing amount than the power P2 to the intermediate power Pm1 that does not reliably extinguish the plasma. Thus, the power can reliably reach the lowered power Pg while preventing the plasma from being extinguished.

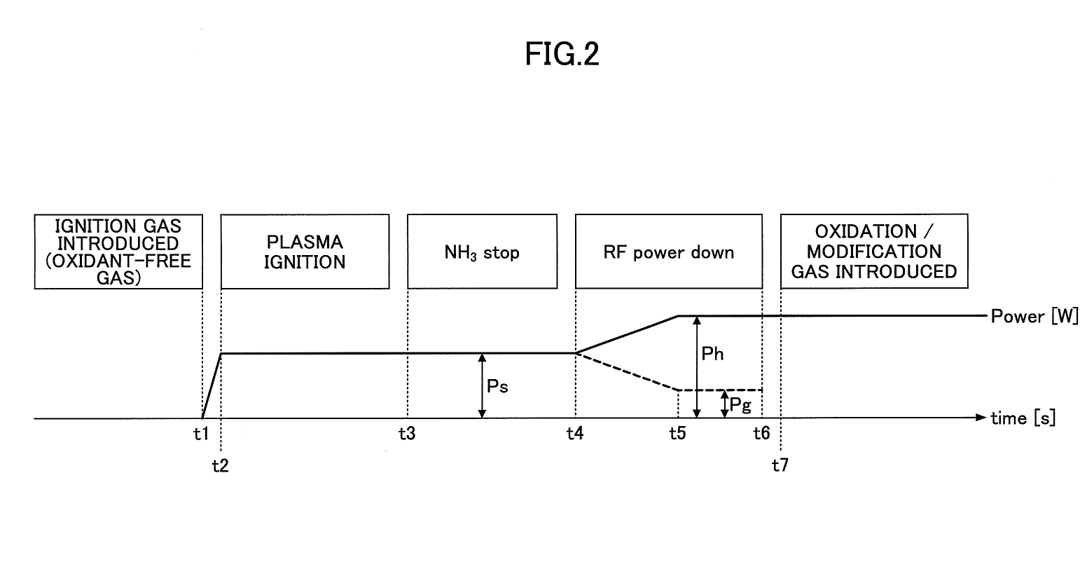

FIG. 2 is a diagram illustrating a conventional sequence of a comparative example. In FIG. 2, because the sequence until time t4 is the same as that in FIG. 1 as described in the plasma generation method according to the first embodiment, the description is omitted.

A period from time t4 to time t5 is a period for increasing the output of the radio frequency power source in the conventional sequence. Such a sequence can increase the input power to the plasma generator to power Ph and can reliably generate and maintain the plasma, but thins the undercoat film when generating the oxidation plasma.

On the other hand, as expressed by a dotted line, when the input power is decreased to the lowered power Pg described in FIG. 1 during the period from time t4 to time t5, the plasma is extinguished at time t5 or immediately after time t5. When the input power is decreased to the lowered power Pg of the target value at once instead of decreasing in stages, the plasma is extinguished because the plasma cannot tolerate the drastic change.

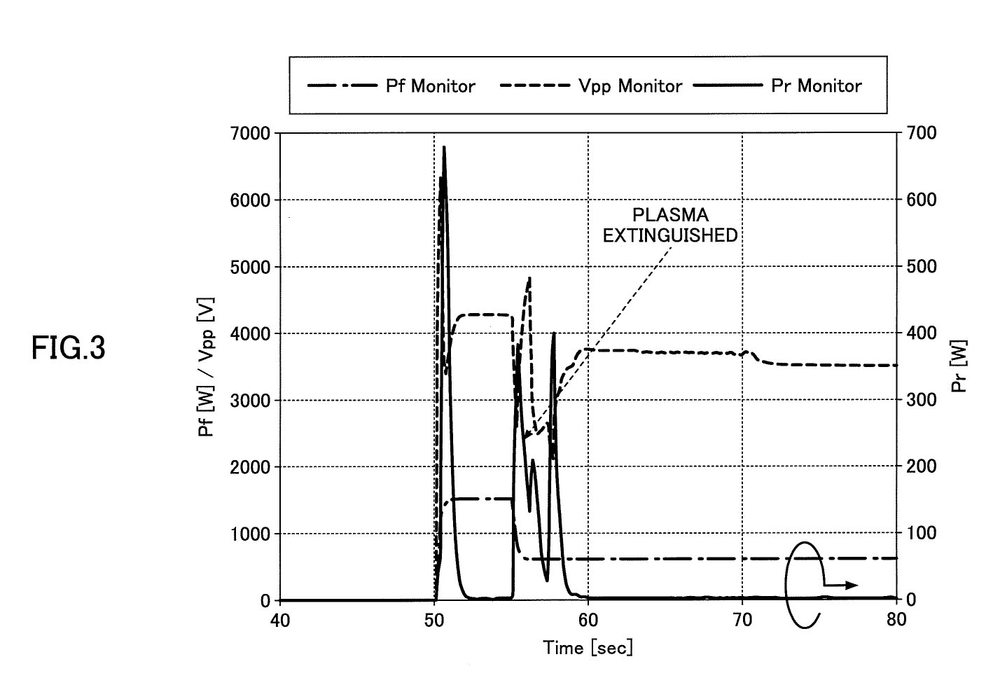

FIG. 3 is a diagram illustrating a state of plasma in a conventional sequence according to a comparative example. As illustrated in FIG. 3, when the normal power Ps (shown by “Pf Monitor”, dashed-dotted line) is set at 1500 W and the lowered power Pg of the target value is set at 600 W, the plasma (shown by “Pr Monitor”, solid line) is extinguished during a period from time 50 to 60 [seconds], and the output (shown by “Vpp Monitor”, dashed line) decreases at once. More specifically, the plasma is ignited at 50 seconds, and then fluctuates between 55 and 60 seconds when the input power is lowered and is finally extinguished during the period.

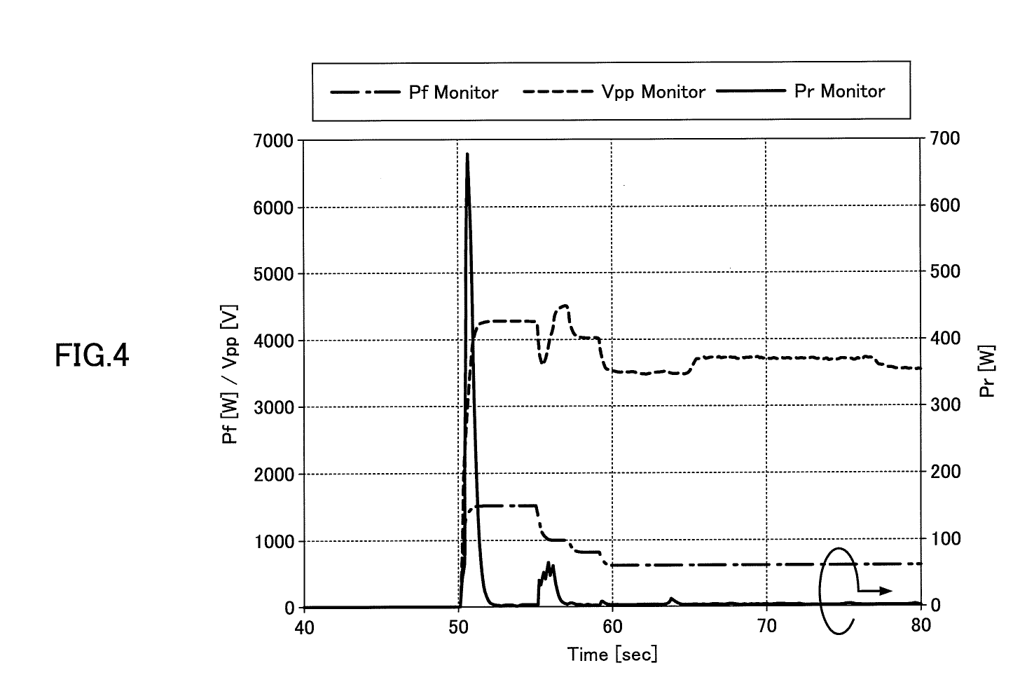

FIG. 4 is a diagram illustrating a state of plasma of the plasma generation method according to the first embodiment of the present disclosure. As illustrated in FIG. 4, in the plasma generation method according to the first embodiment, the output (shown by “Vpp Monitor”, dashed line) can be decreased in a staircase manner similar to the input power (shown by “Pf Monitor”, dashed-dotted line), and can be decreased while maintaining the plasma (shown by “Pr Monitor”, solid line). More specifically, the plasma slightly fluctuates at 50 seconds when the input power is lowered, but becomes stable soon at around 58 seconds, and then keeps stable after that. In such a manner, thinning the undercoat film can be prevented.

Thus, according to the plasma generation method of the first embodiment of the present disclosure, by decreasing the input power to the plasma generator gradually in a staircase manner, the plasma energy can be decreased while preventing the plasma from being extinguished.

### Second Embodiment

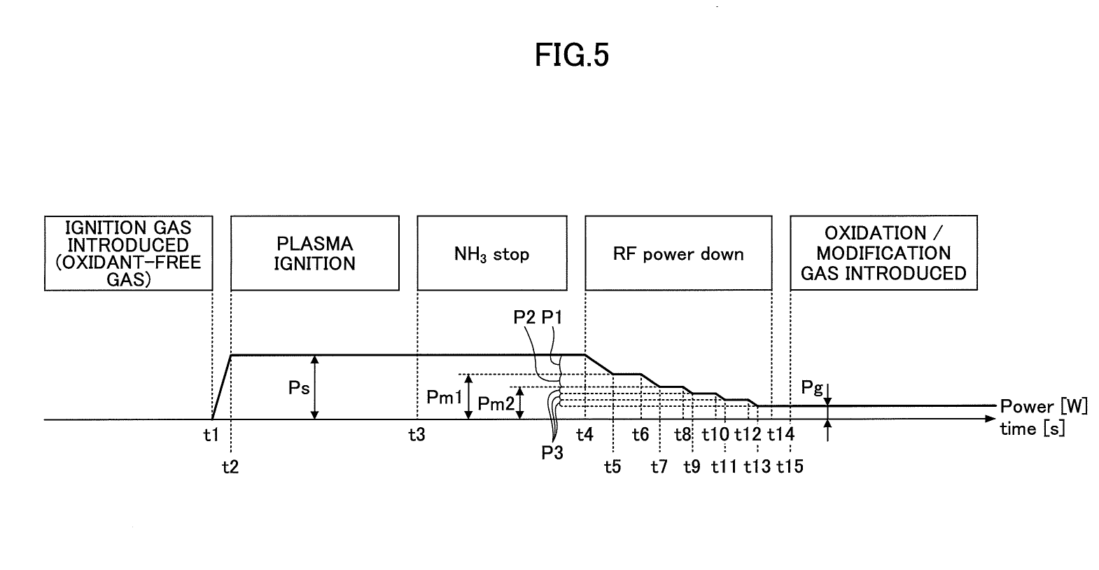

FIG. 5 is a diagram illustrating an example of a plasma generation method according to a second embodiment of the present disclosure. As illustrated in FIG. 5, in the plasma generation method according to the second embodiment, power P3 is the lowest amount of decreasing power. The power reaches intermediate power Pm1 by decreasing the power from normal power Ps by the power P1, and then reaches intermediate power Pm2 by decreasing the power by power P2. Thus, the intermediate power may be divided into 2-stage intermediate power Pm1 and Pm2. The power P2 is set at a value that is lower than the power P1 and higher than the power P3. Such a setting allows the intermediate power Pm2 to be set at a value lower than the intermediate power Pm1 and the power Pm2 of the first embodiment. In this case, the intermediate power Pm2 is set at a value having a level that is not reliably extinguished when the power is decreased in two stages.

For example, when the normal power Ps is set at 1500 W or 2000 W, the intermediate power Pm1 can be set at a value higher than 1000 W, and the intermediate power Pm2 can be set at a value lower than 1000 W. Naturally, in terms of reliably preventing the plasma from being extinguished, both of the intermediate power Pm1 and Pm2 can be set 1000 W or higher.

In contrast, the power P3 for repeatedly decreasing the power is set at the lowest amount of decreasing power similar to the first embodiment. For example, the power P3 may be set at about 200 W similar to the first embodiment. Because the sequence after time t7 is similar to the sequence after time t5 of the first embodiment, the description is omitted.

According to the plasma generation method of the second embodiment, the input power can be decreased in two stages before decreasing the power by the power P3, and an appropriate power decreasing sequence can be flexibly configured depending on a process.

### Third Embodiment

In a third embodiment of the present disclosure, an example of applying the plasma generation methods according to the first and second embodiments to a plasma processing apparatus is described below.

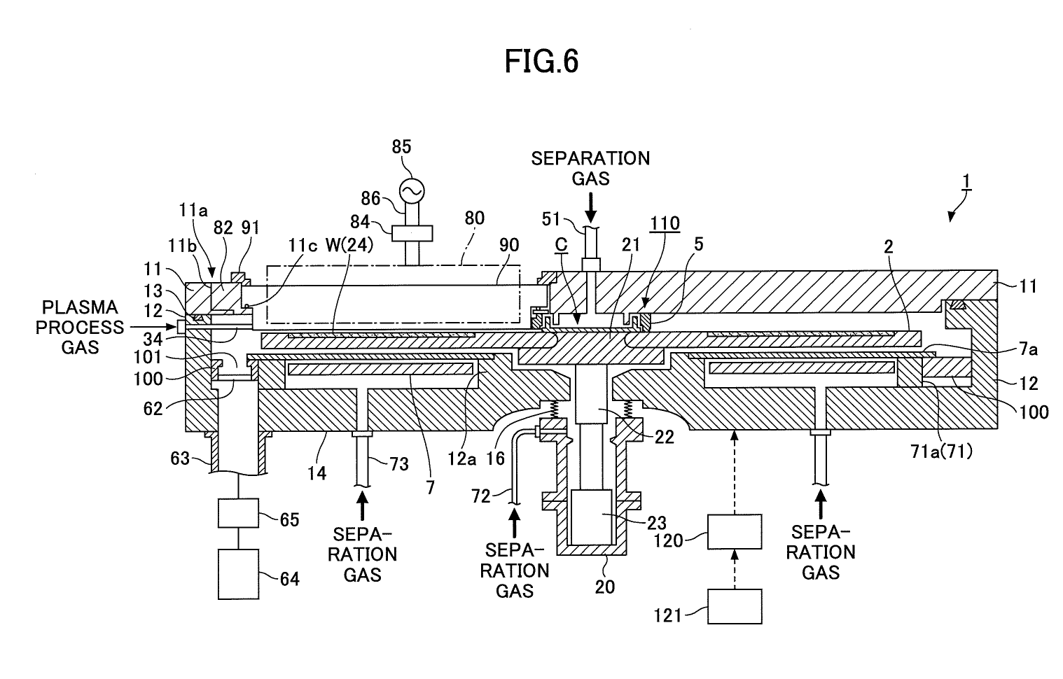

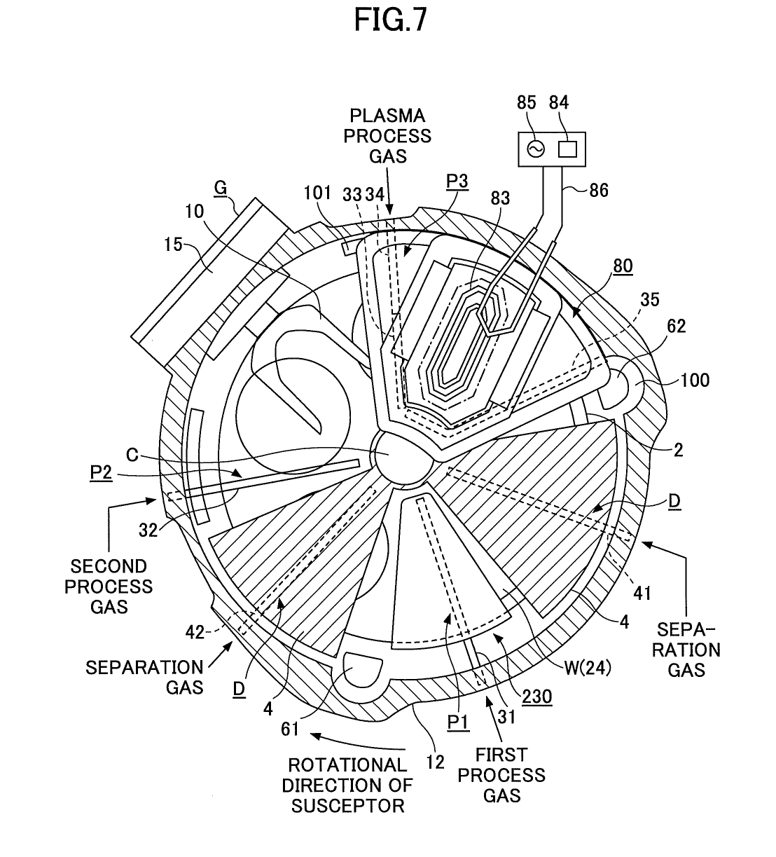

FIG. 6 is a schematic vertical cross-sectional view illustrating an example of a plasma processing apparatus according to an embodiment of the present disclosure. FIG. 7 is a schematic plan view illustrating an example of the plasma processing apparatus according to the embodiment. In FIG. 7, for convenience of explanation, a depiction of a top plate 11 is omitted.

As illustrated in FIG. 6, the plasma processing apparatus of the embodiment includes a vacuum chamber 1 having a substantially circular planar shape, and a susceptor 2 that is disposed in the vacuum chamber 1 such that the rotational center of the susceptor 2 coincides with the center of the vacuum chamber 1. The susceptor 2 rotates wafers W placed thereon by rotating around its rotational center.

The vacuum chamber 1 is a process chamber to accommodate wafers W therein and to perform a plasma process on a film or the like deposited on surfaces of the wafers W. The vacuum chamber 1 includes a top plate (ceiling) 11 that faces concave portions 24 formed in a surface of the susceptor 2, and a chamber body 12. A ring-shaped seal member 13 is provided at the periphery of the upper surface of the chamber body 12. The top plate 11 is configured to be attachable to and detachable from the chamber body 12. The diameter (inside diameter) of the vacuum chamber 1 in plan view is, for example, about 1100 mm, but is not limited to this.

A separation gas supply pipe 51 is connected to the center of the upper side of the vacuum chamber 1 (or the center of the top plate 11). The separation gas supply pipe 51 supplies a separation gas to a central area C in the vacuum chamber 1 to prevent different process gases from mixing with each other in the central area C.

A central part of the susceptor 2 is fixed to an approximately-cylindrical core portion 21. A rotational shaft 22 is connected to a lower surface of the core portion 21 and extends in the vertical direction. The susceptor 2 is configured to be rotatable by a drive unit 23 about the vertical axis of the rotational shaft 22, in a clockwise fashion in the example of FIG. 2. The diameter of the susceptor 2 is, for example, but is not limited to, about 1000 mm.

The rotational shaft 22 and the drive unit 23 are housed in a case body 20. An upper-side flange of the case body 20 is hermetically attached to the lower surface of a bottom part 14 of the vacuum chamber 1. A purge gas supply pipe 72 is connected to the case body 20. The purge gas supply pipe 72 supplies a purge gas (separation gas) such as argon gas to an area below the susceptor 2.

A part of the bottom part 14 of the vacuum chamber 1 surrounding the core portion 21 forms a ring-shaped protrusion 12a that protrudes so as to approach the susceptor 2 from below.

Circular concave portions 24 (or substrate receiving areas), where the wafers W having a diameter of, for example, 300 mm are placed, are formed in the upper surface of the susceptor 2. A plurality of (e.g., five) concave portions 24 are provided along the rotational direction of the susceptor 2. Each of the concave portions 24 has an inner diameter that is slightly (e.g., from 1 mm to 4 mm) greater than the diameter of the wafer W. The depth of the concave portion 24 is substantially the same as or greater than the thickness of the wafer W. Accordingly, when the wafer W is placed in the concave portion 24, the height of the upper surface of the wafer W becomes substantially the same as or lower than the height of the upper surface of the susceptor 2 where the wafers W are not placed. When the depth of the concave portion 24 is excessively greater than the thickness of the wafer W, it may adversely affect film deposition. Therefore, the depth of the concave portion 24 is preferably less than or equal to about three times the thickness of the wafer W. Through holes (not illustrated in the drawings) are formed in the bottom of the concave portion 24 to allow a plurality of (e.g., three) lifting pins (which are described later) to pass through. The lifting pins raise and lower the wafer W.

As illustrated in FIG. 7, a first process region P1, a second process region P2 and a third process region P3 are provided apart from each other along the rotational direction of the susceptor 2. Because the third process region P3 is a plasma processing region, it may be also referred to as a plasma processing region P3 hereinafter. A plurality of (e.g., seven) gas nozzles 31, 32, 33, 34, 35, 41, and 42 made of, for example, quartz are arranged at intervals in a circumferential direction of the vacuum chamber 1. The gas nozzles 31 through 35, 41, and 42 extend radially, and are disposed to face regions that the concave portions 24 of the susceptor 2 pass through. The nozzles 31 through 35, 41, and 42 are placed between the susceptor 2 and the top plate 11. Here, each of the gas nozzles 31 through 35, 41, and 42 extends horizontally from the outer wall of the vacuum chamber 1 toward the central area C so as to face the wafers W. On the other hand, the gas nozzle 35 extends from the outer wall of the vacuum chamber 1 toward the central area C, and then bends and extends linearly along the central area C in a counterclockwise fashion (opposite direction of the rotational direction of the susceptor 2). In the example of FIG. 7, plasma process gas nozzles 33 and 34, a plasma process gas nozzle 35, a separation gas nozzle 41, a first process gas nozzle 31, a separation gas nozzle 42 and a second process gas nozzle 32 are arranged in a clockwise fashion (the rotational direction of the susceptor 2) from a transfer opening 15 in this order. Here, a gas supplied from the second process gas nozzle 32 is often similar to a gas supplied from the plasma process gas nozzles 33 through 35, but the second process gas nozzle 32 may not be necessarily provided when the plasma process gas nozzles 33 through 35 sufficiently supply the gas.

Moreover, the plasma process gas nozzles 33 through 35 may be replaced by a single plasma process gas nozzle. In this case, for example, a plasma process gas nozzle extending from the outer peripheral wall of the vacuum chamber 1 toward the central area C may be provided similar to the second process gas nozzle 32.

The first process gas nozzle 31 forms a “first process gas supply part.” The second process gas nozzle 32 forms a “second process gas supply part.” Each of the plasma process gas nozzles 33, 34 and 35 forms a “plasma process gas supply part”. Each of the separation gas nozzles 41 and 42 forms a “separation gas supply part”.

Each of the process gas nozzles 31 through 35, 41, and 42 is connected to each gas supply source (not illustrated in the drawings) via a flow control valve.

Gas discharge holes 36 for discharging a gas are formed in the lower side (which faces the susceptor 2) of each of the nozzles 31 through 35, 41, and 42. The gas discharge holes 36 are formed, for example, at regular intervals along the radial direction of the susceptor 2. The distance between the lower end of each of the nozzles 31 through 35, 41, and 42 and the upper surface of the susceptor 2 is, for example, from about 1 mm to about 5 mm.

A region below the first process gas nozzle 31 is a first process region P1 where a first process gas adsorbs on the wafer W. A region below the second process gas nozzle 32 is a second process region P2 where a second process gas that can produce a reaction product by reacting with the first process gas is supplied to the wafer W. A region below the plasma process gas nozzles 33 through 35 is a third process region P3 where a modification process is performed on a film on the wafer W. The separation gas nozzles 41 and 42 are provided to form separation regions D for separating the first process region P1 from the second process region P2, and separating the third process region P3 from the first process region P1, respectively. Here, the separation region D is not provided between the second process region P2 and the third process region P3. This is because the second process gas supplied in the second process region P2 and the mixed gas supplied in the third process region P3 partially contain a common component therein in many cases, and therefore the second process region P2 and the third process region P3 do not have to be separated from each other by particularly using the separation gas.

Although described in detail below, the first process gas nozzle 31 supplies a source gas that forms a principal component of a film to be deposited. For example, when the film to be deposited is a silicon oxide film (SiO₂), the first process gas nozzle 31 supplies a silicon-containing gas such as an organic aminosilane gas. The second process gas nozzle 32 supplies an oxidation gas such as oxygen gas and ozone gas. The plasma process gas nozzles 33 through 35 supply a mixed gas containing the same gas as the second process gas and a noble gas to perform a modification process on the deposited film. For example, when the film to be deposited is the silicon oxide film (SiO₂), the plasma process gas nozzles 33 through 35 supply a mixed gas of the oxidation gas such as oxygen gas and ozone gas same as the second process gas and a noble gas such as argon and helium. Here, because the plasma process gas nozzles 33 through 35 are structured to supply the gas to different areas on the susceptor 2, the flow rate of the noble gas may be changed for each area so as to uniformly perform the modification process as a whole.

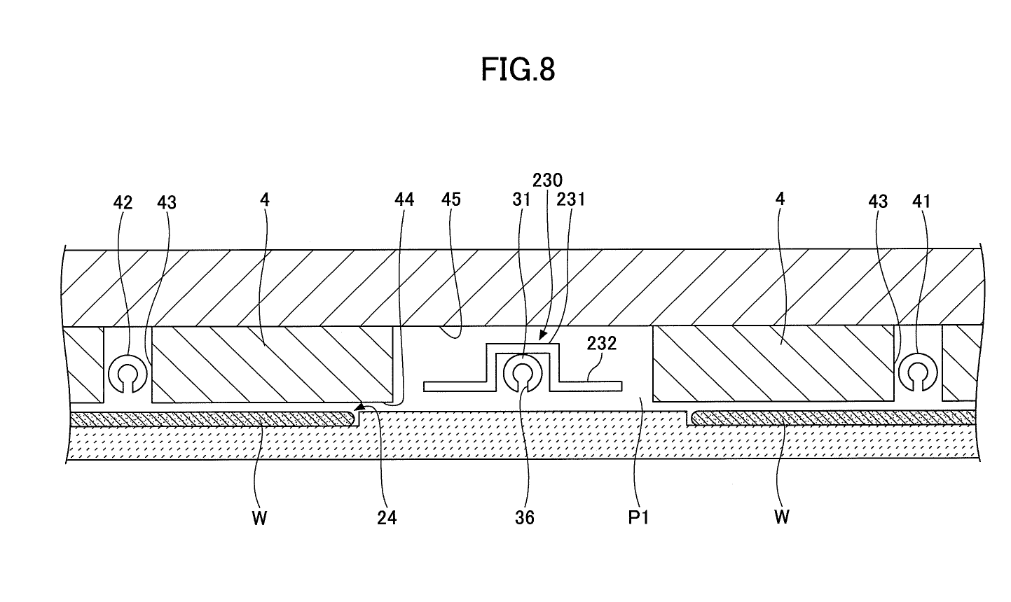

FIG. 8 illustrates a cross section of a part of the plasma processing apparatus taken along a concentric circle of the susceptor 2. More specifically, FIG. 8 illustrates a cross section of a part of the plasma processing apparatus from one of the separation regions D through the first process region P1 to the other one of the separation regions D.

Approximately fan-like convex portions 4 are provided on the lower surface of the top plate 11 of the vacuum chamber 1 at locations corresponding to the separation areas D. The convex portions 4 are attached to the back surface of the top plate 11. In the vacuum chamber 1, flat and low ceiling surfaces 44 (first ceiling surfaces) are formed by the lower surfaces of the convex portions 4, and ceiling surfaces 45 (second ceiling surfaces) are formed by the lower surface of the top plate 11. The ceiling surfaces 45 are located on both sides of the ceiling surfaces 44 in the circumferential direction, and are located higher than the ceiling surfaces 44.

As illustrated in FIG. 7, each of the convex portions 4 forming the ceiling surface 44 has a fan-like planar shape whose apex is cut off to form an arc-shaped side. Also, a groove 43 extending in the radial direction is formed in each of the convex portions 4 at the center in the circumferential direction. Each of the separation gas nozzles 41 and 42 is placed in the groove 43. A peripheral part of the convex portion 4 (a part along the outer edge of the vacuum chamber 1) is bent to form an L-shape to prevent the process gases from mixing with each other. The L-shaped part of the convex portion 4 faces the outer end surface of the susceptor 2 and is slightly apart from the chamber body 12.

A nozzle cover 230 is provided above the first process gas nozzle 31. The nozzle cover 230 causes the first process gas to flow along the wafer W, and causes the separation gas to flow near the top plate 11 instead of near the wafer W. As illustrated in FIG. 3, the nozzle cover 230 includes an approximately-box-shaped cover body 231 having an opening in the lower side to accommodate the first process gas nozzle 31, and current plates 232 connected to the upstream and downstream edges of the opening of the cover body 231 in the rotational direction of the susceptor 2. A side wall of the cover body 231 near the rotational center of the susceptor 2 extends toward the susceptor 2 to face a tip of the first process gas nozzle 31. Another side wall of the cover 231 near the outer edge of the susceptor 2 is partially cut off so as not to interfere with the first process gas nozzle 31.

As illustrated in FIG. 7, a plasma generator 80 is provided above the plasma process gas nozzles 33 through 35 to convert a plasma process gas discharged into the vacuum chamber 1 to plasma.

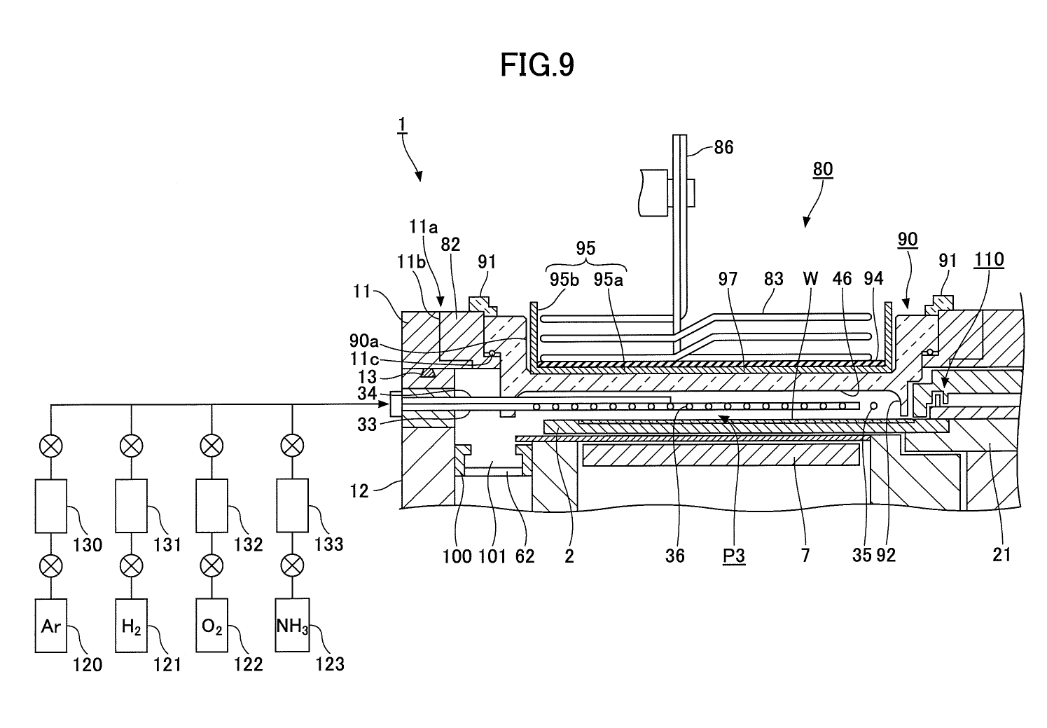

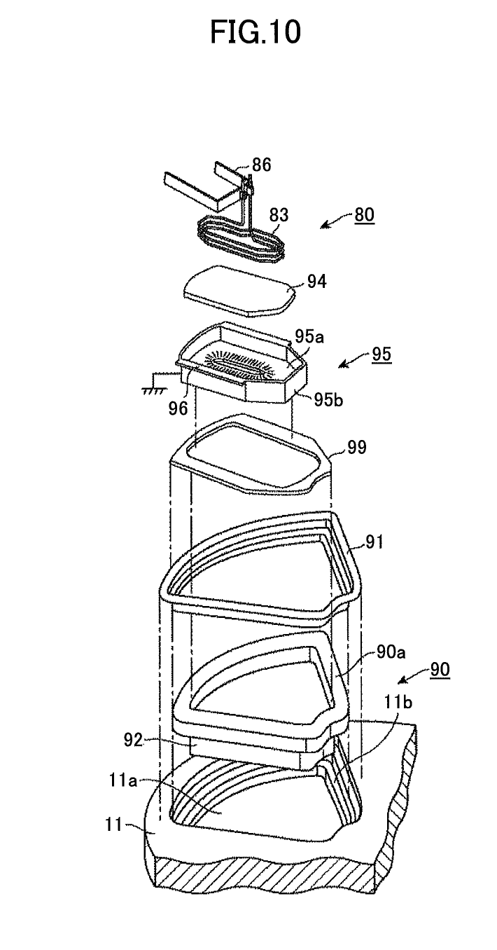

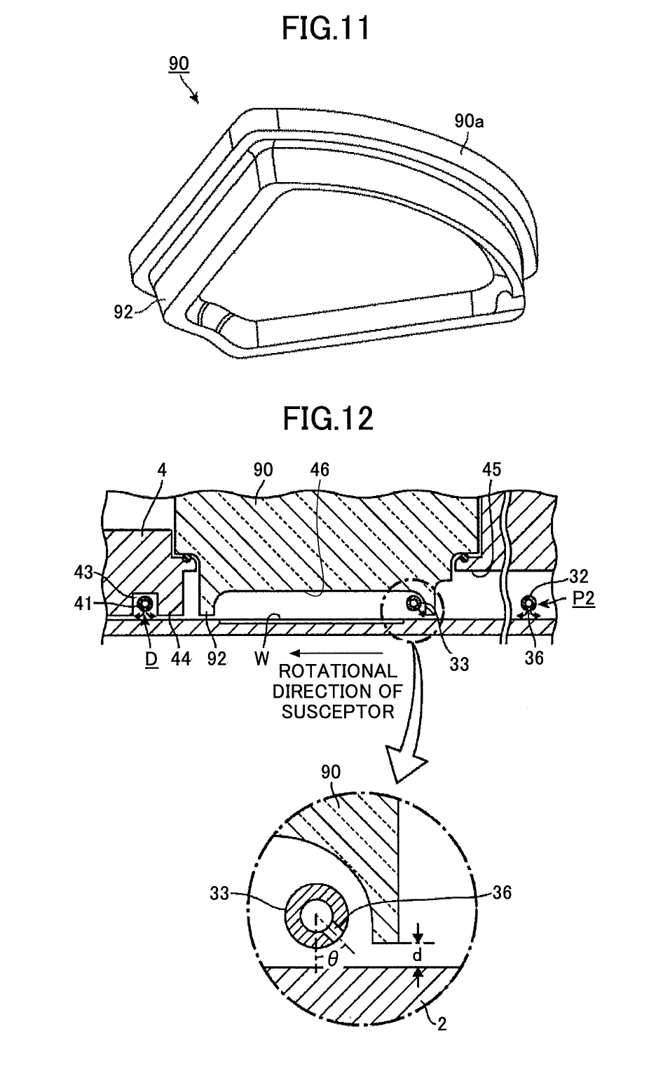

FIG. 9 is a vertical cross-sectional view of an example of the plasma generator 80. FIG. 10 is an exploded perspective view of an example of the plasma generator 80. FIG. 11 is a perspective view of an example of a housing 90 of the plasma generator 80.

The plasma generator 80 is configured by winding an antenna 83 made of a metal wire or the like, for example, three times around a vertical axis in a coil form. In a plan view, the plasma generator 80 is disposed to surround a strip-shaped area extending in the radial direction of the susceptor 2 and to extend across the diameter of the wafer W on the susceptor 2.

The antenna 83 is connected through a matching box 84 to a radio frequency power source 85 that has, for example, a frequency of 13.56 MHz and output power of 5000 W. The antenna 83 is hermetically separated from the inner area of the vacuum chamber 1. As illustrated in FIGS. 7 and 9, a connection electrode 86 is provided to electrically connect the antenna 83 with the matching box 84 and the high frequency power source 85.

As illustrated in FIGS. 9 and 10, an opening 11a having an approximately fan-like shape in a planar view is formed in the top plate 11 above the plasma process gas nozzles 33 through 35.

As illustrated in FIG. 9, a ring-shaped member 82 is hermetically attached to the periphery of the opening 11a. The ring-shaped member 82 extends along the periphery of the opening 11a. The housing 90 is hermetically attached to the inner circumferential surface of the ring-shaped member 82. That is, the outer circumferential surface of the ring-shaped member 82 faces an inner surface 11b of the opening 11a of the top plate 11, and the inner circumferential surface of the ring-shaped member 82 faces a flange part 90a of the housing 90. The housing 90 is placed via the ring-shaped member 82 in the opening 11a to enable the antenna 83 to be placed at a position lower than the top plate 11. The housing 90 may be made of a dielectric material such as quartz. The bottom surface of the housing 90 forms a ceiling surface 46 of the plasma processing region P3.

As illustrated in FIG. 11, an upper peripheral part surrounding the entire circumference of the housing 90 extends horizontally to form the flange part 90a. Moreover, a central part of the housing 90 in a planar view is recessed toward the inner area of the vacuum chamber 1.

The housing 90 is arranged so as to extend across the diameter of the wafer W in the radial direction of the susceptor 2 when the wafer W is located under the housing 90. A seal member 11c such as an O-ring is provided between the ring-shaped member 82 and the top plate 11.

The internal atmosphere of the vacuum chamber 1 is hermetically sealed by the ring-shaped member 82 and the housing 90. As illustrated in FIG. 10, the ring-shaped member 82 and the housing 90 are placed in the opening 11a, and the entire circumference of the housing 90 is pressed downward via a frame-shaped pressing member 91 that is placed on the upper surfaces of the ring-shaped member 82 and the housing 90 and extends along a contact region between the ring-shaped member 82 and the housing 90. The pressing member 91 is fixed to the top plate 11 with, for example, bolts (not illustrated in the drawing). As a result, the internal atmosphere of the vacuum chamber 1 is sealed hermetically. In FIG. 10, a depiction of the ring-shaped member 82 is omitted for simplification.

As illustrated in FIG. 11, the housing 90 also includes a protrusion 92 that extends along the circumference of the housing 90 and protrudes vertically from the lower surface of the housing 90 toward the susceptor 2. The protrusion 92 surrounds the second process region P2 below the housing 90. The plasma process gas nozzles 33 through 35 are accommodated in an area surrounded by the inner circumferential surface of the protrusion 92, the lower surface of the housing 90, and the upper surface of the susceptor 2. A part of the protrusion 92 near a base end (at the inner wall of the vacuum chamber 1) of each of the plasma process gas nozzles 33 through 35 is cut off to form an arc-shaped cut-out that conforms to the outer shape of each of the plasma process gas nozzles 33 through 35.

As illustrated in FIG. 9, on the lower side (i.e., the second process region P2) of the housing 90, the protrusion 92 is formed along the circumference of the housing 90. The protrusion 92 prevents the seal member 11c from being directly exposed to plasma, i.e., isolates the seal member 11c from the second process region P2. This causes plasma to pass through an area under the protrusion 92 even when plasma spreads from the second process region P2 toward the seal member 11c, thereby deactivating the plasma before reaching the seal member 11c.

Moreover, as illustrated in FIG. 9, the plasma process gas nozzles 33 through 35 are provided in the third process region P3 under the housing 90, and are connected to an argon gas supply source 120, a hydrogen gas supply source 121, an oxygen gas supply source 122, and an ammonia gas supply source 123, respectively. Furthermore, corresponding flow controllers 130, 131, 132 and 133 are provided between the plasma process gas nozzles 33 through 35 and the argon gas supply source 120, the hydrogen gas supply source 121, the oxygen gas supply source 122, and the ammonia gas supply source 123, respectively. Ar gas, H₂ gas, O₂ gas and NH₃ gas are supplied from the argon gas supply source 120, the hydrogen gas supply source 121, the oxygen gas supply source 122, and the ammonia gas supply source 123 to each of the plasma process gas nozzles 33 through 35 at predetermined flow rates (mixing ratios, mix proportions) through each of the flow controllers 130, 131, 132 and 133, and the flow rates thereof are determined depending on the areas to be supplied.

Here, when the plasma process gas nozzle is constituted of a single gas nozzle, for example, the above-mentioned mixed gas of Ar gas, H₂ gas, O₂ gas and NH₃ gas is supplied from the single plasma gas nozzle.

FIG. 12 is a vertical cross-sectional view of the vacuum chamber 1 taken along the rotational direction of the susceptor 2. As illustrated in FIG. 12, because the susceptor 2 rotates in a clockwise fashion during the plasma process, N₂ gas is likely to intrude into an area under the housing 90 from a clearance between the susceptor 2 and the protrusion 92 by being brought by the rotation of the susceptor 2. To prevent Ar gas from intruding into the area under the housing 90 through the clearance, a gas is discharged to the clearance from the area under the housing 90. More specifically, as illustrated in FIGS. 9 and 12, the gas discharge holes 36 of the plasma process gas nozzle 34 are arranged to face the clearance, that is, to face the upstream side in the rotational direction of the susceptor 2 and downward. A facing angle θ of the gas discharge holes 36 of the plasma process gas nozzle 33 relative to the vertical axis may be, for example, about 45 degrees as illustrated in FIG. 12, or may be about 90 degrees so as to face the inner side wall of the protrusion 92. In other words, the facing angle θ of the gas discharge holes 36 may be set at an appropriate angle capable of properly preventing the intrusion of N₂ gas in a range from about 45 to about 90 degrees depending on the intended use.

FIG. 13 is an enlarged perspective view illustrating the plasma process gas nozzles 33 through 35 provided in the plasma process region P3. As illustrated in FIG. 8, the plasma process gas nozzle 33 is a nozzle capable of entirely covering the concave portion 24 in which the wafer W is placed, and supplying a plasma process gas to the entire surface of the wafer W. On the other hand, the plasma process gas nozzle 34 is a nozzle provided slightly above the plasma process gas nozzle 33 so as to approximately overlap with the plasma process gas nozzle 33. The length of the plasma process gas nozzle 34 is about half the length of the plasma process gas nozzle 33. The plasma process gas nozzle 35 extends from the outer peripheral wall of the vacuum chamber 1 along the radius of the downstream side of the fan-like plasma process region P3 in the rotational direction of the susceptor 2, and has a shape bent linearly along the central area C after reaching the neighborhood of the central area C. Hereinafter, for convenience of distinction, the plasma process gas nozzle 33 covering the whole area may be referred to as a base nozzle 33, and the plasma process gas nozzle 34 covering only the outer area may be referred to as an outer nozzle 34. Also, the plasma process gas nozzle 35 extending to the inside may be referred to as an axis-side nozzle 35.

The base nozzle 33 is a gas nozzle for supplying a plasma process gas to the whole surface of the wafer W. As illustrated in FIG. 12, the base gas nozzle 33 discharges the plasma process gas toward the protrusion 92 forming the side surface that separates the plasma process region P3 from the other area.

On the other hand, the outer nozzle 34 is a nozzle for supplying a plasma process gas selectively to an outer area of the wafer W.

The axis-side nozzle 35 is a nozzle for supplying a plasma process gas selectively to a central area near the axis of the susceptor 2 of the wafer W.

When a single nozzle is provided as the plasma process gas nozzle instead of the process gas nozzles 33 through 35, only the base nozzle 33 just has to be provided.

Next, a Faraday shield 95 of the plasma generator 80 is described below. As illustrated in FIGS. 9 and 10, a Faraday shield 95 is provided on the upper side of the housing 90. The Faraday shield 95 is grounded, and is composed of a conductive plate-like part such as a metal plate (e.g., copper plate) that is shaped to roughly conform to the internal shape of the housing 90. The Faraday shield 95 includes a horizontal surface 95a that extends horizontally along the bottom surface of the housing 90, and a vertical surface 95b that extends upward from the outer edge of the horizontal surface 95a and surrounds the horizontal surface 95a. The Faraday shield 95 may be configured to be, for example, a substantially hexagonal shape in a plan view.

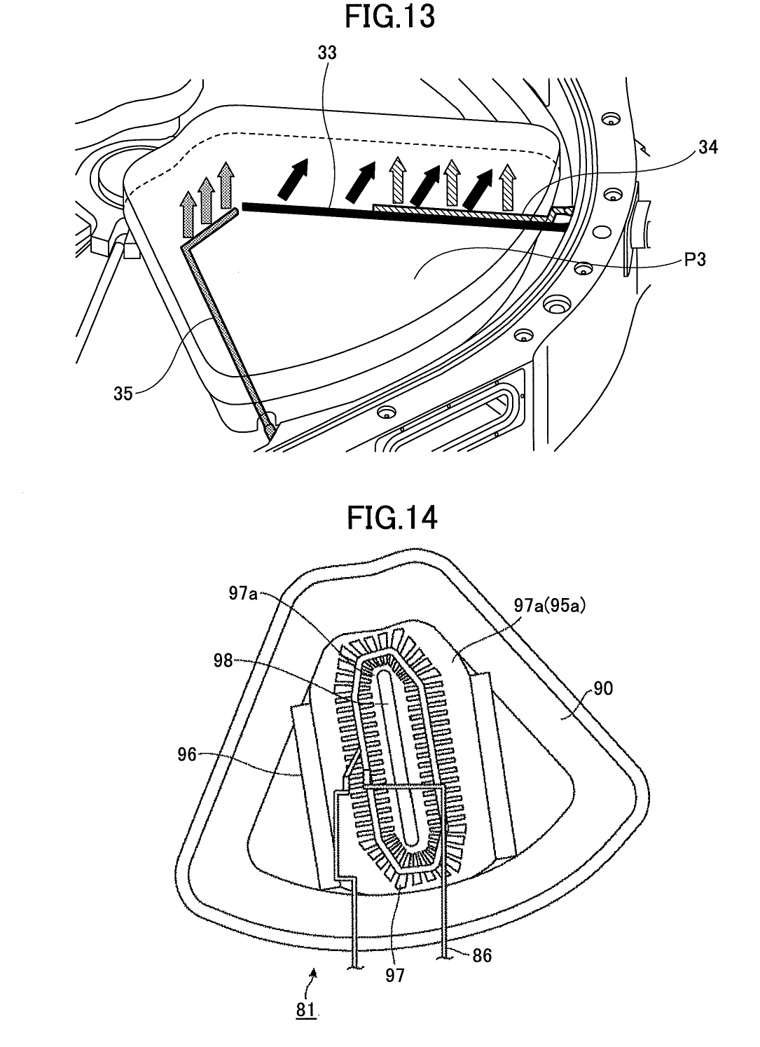

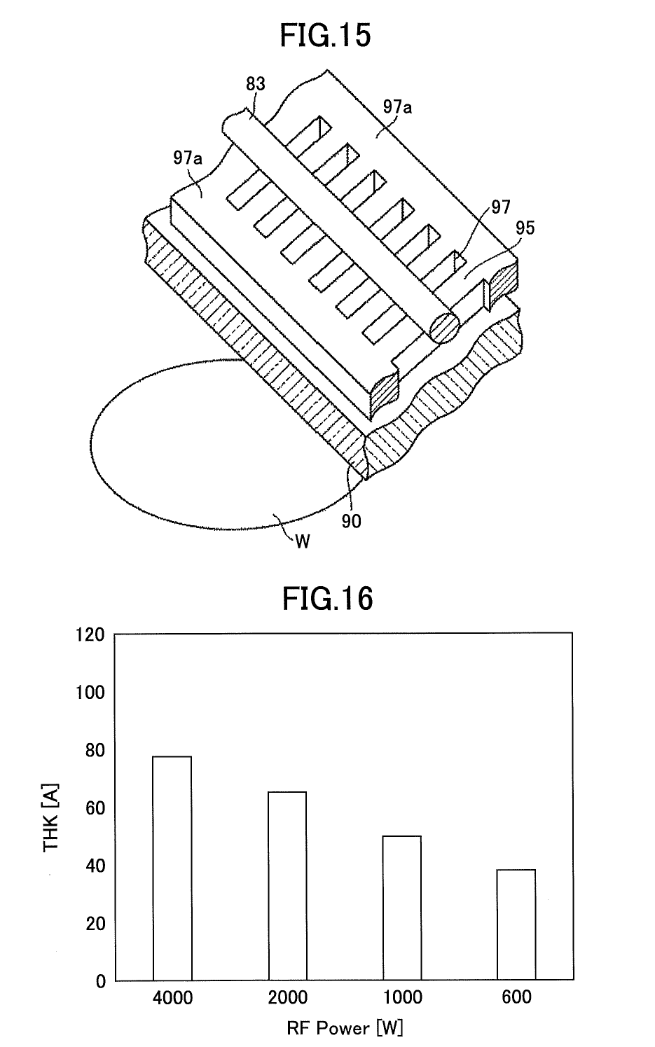

FIG. 14 is a plan view of an example of the plasma generator 80. FIG. 15 is a perspective view of a part of the Faraday shield 95 provided in the plasma generator 80.

When seen from the rotational center of the susceptor 2, the right and left upper ends of the Faraday shield 95 extend horizontally rightward and leftward, respectively, to form supports 96. As illustrated in FIG. 10, a frame 99 is provided between the Faraday shield 95 and the housing 90 to support the supports 96 from below. The frame 99 is supported by a part of the housing 90 near the central area C and a part of the flange part 90a near the outer edge of the susceptor 2.

When an electric field reaches the wafer W, for example, electric wiring and the like formed inside the wafer W may be electrically damaged. To prevent this problem, as illustrated in FIG. 15, many slits 97 are formed in the horizontal surface 95a. The slits 97 prevent an electric-field component of an electric field and a magnetic field (electromagnetic field) generated by the antenna 83 from reaching the wafer W below the Faraday shield 95, and allow a magnetic field component of the electromagnetic field to reach the wafer W.

As illustrated in FIGS. 14 and 15, the slits 97 extend in directions that are orthogonal to the direction in which the antenna 83 is wound, and are arranged to form a circle below the antenna 83. The width of each slits 97 is set at a value that is about 1/10000 or less of the wavelength of radio frequency power supplied to the antenna 83. Circular electrically-conducting paths 97a made of, for example, a grounded conductor are provided at the ends in the length direction of the slits 97 to close the open ends of the slits 97. An opening 98 is formed in an area of the Faraday shield 95 where the slits 97 are not formed, i.e., an area surrounded by the antenna 83. The opening 98 is used to check whether plasma is emitting light. In FIG. 7, the slits 97 are omitted for simplification, but an area where the slits 97 are formed is indicated by a dashed-dotted line.

As illustrated in FIG. 10, an insulating plate 94 is stacked on the horizontal surface 95a of the Faraday shield 95. The insulating plate 94 is made of, for example, quartz having a thickness of about 2 mm, and is used for insulation between the Faraday shield 95 and the plasma generator 80 disposed above the Faraday shield 95. Thus, the plasma generator 80 is arranged to cover the inside of the vacuum chamber 1 (i.e., the wafer W on the susceptor 2) through the housing 90, the Faraday shield 95, and the insulating plate 94.

Again, other components of the plasma processing apparatus according to the present embodiment are described below.

As illustrated in FIG. 2, a side ring 100, which is a cover, is provided along the outer circumference of the susceptor 2 and slightly below the susceptor 2. First and second exhaust openings 61 and 62, which are apart from each other in the circumferential direction, are formed in the upper surface of the side ring 100. More specifically, the first and second exhaust openings 61 and 62 are formed in the side ring 100 at locations that correspond to exhaust ports formed in the bottom surface of the vacuum chamber 1.

In the present embodiment, one and the other of the exhaust openings 61 and 62 are referred to as a first exhaust opening 61 and a second exhaust opening 62, respectively. The first exhaust opening 61 is formed at a location that is between the first process gas nozzle 31 and the separation area D located downstream of the first process gas nozzle 31 in the rotational direction of the susceptor 2, and is closer to the separation area D than to the first process gas nozzle 31. The second exhaust opening 62 is formed at a location that is between the plasma generator 80 and the separation area D located downstream of the plasma generator 80 in the rotational direction of the susceptor 2, and is closer to the separation area D than to the plasma generator 80.

The first exhaust opening 61 is configured to evacuate the first process gas and the separation gas, and the second exhaust opening 62 is configured to evacuate the plasma process gas and the separation gas. Each of the first exhaust opening 61 and the second exhaust opening 62 is connected to a vacuum pump 64 that is an example of an evacuation mechanism through an exhaust pipe 63 including a pressure controller 65 such as a butterfly valve.

Here, gases flowing from the upstream in the rotational direction of the susceptor 2 to the third process region P3 and then flowing toward the second exhaust opening 62 may be blocked by the housing 90 extending from the central area C toward the outer wall of the vacuum chamber 1. For this reason, a groove-like gas flow passage 101 to allow the gases to flow therethrough is formed in the upper surface of the side ring 100 at a location closer to the outer wall of the vacuum chamber 1 than the outer end of the housing 90.

As illustrated in FIG. 1, a protruding portion 5 having a substantially ring shape is formed on a central part of the lower surface of the top plate 11. The protruding portion 5 is connected with the inner ends (that face the central area C) of the convex portions 4. The height of the lower surface of the protruding portion 5 is substantially the same as the height of the lower surfaces (the ceiling surfaces 44) of the convex portions 4. A labyrinth structure 110 is formed above the core portion 21 at a location closer to the rotational center of the susceptor 2 than the protruding portion 5. The labyrinth structure 110 prevents gases from mixing with each other in the central area C.

As described above, the housing 90 extends up to a location near the central area C. Therefore, the core portion 21 for supporting the central part of the susceptor 2 is formed near the rotational center so that a part of the core portion 21 above the susceptor 2 does not contact the housing 90. For this reason, compared with outer peripheral areas, gases are likely to mix with each other in the central area C. The labyrinth structure 110 above the core portion 21 lengthens gas flow passage and thereby prevents gases from mixing with each other.

As illustrated in FIG. 1, a heater unit 7 is provided in a space between the susceptor 2 and the bottom part 14 of the vacuum chamber 1. The heater unit 7 can heat, through the susceptor 2, the wafer W on the susceptor 2 to a temperature, for example, in a range from about room temperature to about 300 degrees C. In FIG. 1, a side covering member 71a is provided on a lateral side of the heater unit 7, and an upper covering member 7a is provided above the heater unit 7 to cover the heater unit 7. Purge gas supply pipes 73 are provided in the bottom part 14 of the vacuum chamber 1 below the heater unit 7. The purge gas supply pipes 73 are arranged at a plurality of locations along the circumferential direction and used to purge the space where the heater unit 7 is placed.

As illustrated in FIG. 2, the transfer opening 15 is formed in the side wall of the vacuum chamber 1. The transfer opening 15 is used to transfer the wafer W between a transfer arm 10 and the susceptor 2. A gate valve G is provided to hermetically open and close the transfer opening 15.

The wafer W is transferred between the concave portion 24 of the susceptor 2 and the transfer arm 10 when the concave portion 24 is at a position (transfer position) facing the transfer opening 15. For this reason, lifting pins and an elevating mechanism (not illustrated in the drawings) for lifting the wafer W are provided at the transfer position under the susceptor 2. The lifting pins pass through the concave portion 24 and push the back surface of the wafer W upward.

The plasma processing apparatus of the embodiment also includes a controller 120 implemented by a computer for controlling the operations of the entire plasma processing apparatus. The controller 120 includes a memory that stores a program for causing the plasma processing apparatus to perform a substrate process described below. The program may include steps for causing the plasma processing apparatus to perform various operations. The program may be stored in a storage unit 121 that forms a storage medium such as a hard disk, a compact disc, a magneto-optical disk, a memory card, or a flexible disk, and installed from the storage unit 121 into the controller 120.

[Plasma Processing Method]

Next, a plasma processing method using the plasma processing apparatus according to an embodiment of the present disclosure is described below.

To begin with, to carry substrates such as the wafers W into the vacuum chamber 1, the gate valve G is opened. Next, while the susceptor 2 is being rotated intermittently, the wafers W are carried into the vacuum chamber 1 through the transfer opening 15 and placed on the susceptor 2 by the transfer arm 10.

An undercoat film except for an oxide film is formed on the wafer W. As described above, for example, an undercoat film such as SiN film may be formed on the wafer W.

Next, the gate valve G is closed, and the pressure in the vacuum chamber 1 is adjusted to a predetermined pressure value by the vacuum pump 64 and the pressure controller 65. Then, the wafers W are heated to a predetermined temperature by the heater unit 7 while the susceptor 2 is rotated. At this time, a separation gas, for example, Ar gas is supplied from the separation gas nozzles 41 and 42.

Here, the plasma generator 80 is ignited. Each of the plasma process gas nozzles 33 through 35 supplies an ignition gas at a predetermined flow rate. A gas other than an oxidation gas is selected as the ignition gas, and for example, ammonia that is a nitrogen-containing gas is selected as the ignition gas.

After the supply of ammonia is stopped, plasma is generated at low power and is maintained by the plasma generation method according to the first or second embodiment described at FIGS. 1 through 5.

Subsequently, the first process gas nozzle 31 supplies a silicon-containing gas, and the second process gas nozzle 32 supplies an oxidation gas. Moreover, each of the plasma process gas nozzles 33 through 35 supplies an oxidation gas at a predetermined flow rate.

A Si-containing gas or a metal containing gas adsorbs on the surface of the wafer in the first process region P1 due to the rotation of the susceptor 2, and then the Si-containing gas adsorbed on the surface of the wafer W is oxidized by oxygen gas in the second process region P2. Thus, one or more molecular layers of a silicon oxide film that is a component of a thin film are deposited on the surface of the wafer W and a reaction product is deposited on the surface of the wafer W.

When the susceptor 2 further rotates, the wafer W reaches the plasma process region P3, and a modification process of the silicon oxide film by a plasma process is performed. With respect to the plasma process gas supplied in the plasma process region P3, for example, the base nozzle 33 supplies a mixed gas of Ar, He and O₂ containing Ar and He at a mixing ratio of 1:1; the outer nozzle 34 supplies a mixed gas containing Ar and O₂ and not containing He; and the axis-side nozzle 35 supplies a mixed gas containing Ar and O₂ and not containing He. Thus, the base nozzle 33 supplies the mixed gas containing Ar and O₂ at a ratio of 1:1, which is made as a standard, and the mixed gas having a weaker modification effect than the mixed gas supplied from the base nozzle 33 to the central-axis-side area where the moving speed is low and the quantity of plasma process is likely to be great. In contrast, the mixed gas having a stronger modification effect than the mixed gas supplied from the base nozzle 33 is supplied to the peripheral area where the moving speed is high and the quantity of plasma process is likely to be insufficient. By doing this, the influence of the difference of distance from the center of the susceptor 2 can be reduced, and the uniform plasma process can be performed in the radial direction of the susceptor 2.

Here, because the low power plasma is used, the film is deposited without causing the oxidation plasma to thin the undercoat film.

The plasma generator 80 continues to supply the radio frequency power at the predetermined low output.

In the housing 90, the Faraday shield 95 prevents the electric field of the electromagnetic field generated by the antenna 83 from entering the vacuum chamber 1 by reflecting, absorbing or attenuating the electric field.

On the other hand, because the Faraday shield 95 has the slits 97 formed therein, the magnetic field passes through the slits 97 of the Faraday shield 95, and enters the vacuum chamber 1 through the bottom surface of the housing 90. As a result, the plasma process gases convert to plasma due to the magnetic field in an area under the housing 90. This makes it possible to generate plasma including many active species that are less likely to electrically damage the wafer W.

In the present embodiment, by continuing to rotate the susceptor 2, the adsorption of the source gas on the surface of the wafer W, oxidation of components adsorbed on the wafer surface, and plasma modification of the reaction product are performed in this order many times. In other words, the film deposition process by ALD and the modification process of the deposited film are performed many times by the rotation of the susceptor 2.

In the plasma processing apparatus of the present embodiment, the separation areas D are provided between the first and second process regions P1 and P2, and between the third and first process regions P3 and P1 along the circumferential direction of the susceptor 2. Thus, the process gas and the plasma process gas are prevented from mixing with each other by the separation areas D, and are evacuated from the first and second exhaust openings 61 and 62.

### WORKING EXAMPLES

Next, working examples of the present disclosure are described below.

FIG. 16 is a diagram showing a result of performing the plasma processing method of the working examples. In the working examples, a silicon wafer was oxidized using plasma, and input power to a plasma generator was varied.

Regarding process conditions in the working examples, the rotational speed of a susceptor 2 was set at 120 rpm, and the plasma generator 80 supplied a mixed gas of H₂/O₂ at flow rates of 45/75 sccm, respectively, and converted the mixed gas to plasma, thereby oxidizing a surface of the silicon wafer. An inclination angle of the antenna 83 was set at zero degrees, and a process period was set at 10 minutes.

As shown by FIG. 16, a film thickness of the oxidation film thinned as the output power of the radio frequency power 85 was decreased. This means that the oxidizing capacity is decreased. Thus, the working examples have indicated that the oxidizing capacity of the oxidation plasma can be decreased by decreasing the output power of the radio frequency power source 85 supplied to the plasma generator 80 and that the oxidation of the undercoat film can be prevented by performing the plasma generation method according to the present embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A plasma generation method to generate and maintain plasma by supplying a predetermined power that is lower than a normal power to a plasma generator, comprising steps of:
generating plasma of an ignition gas by supplying the normal power to the plasma generator;
decreasing a power supplied to the plasma generator by a first power that is smaller than a difference between the normal power and the predetermined power; and
decreasing the power supplied to the plasma generator by a second power that is smaller than the first power,
wherein the step of decreasing the power supplied to the plasma generator by the second power is performed after the step of decreasing the power supplied to the plasma generator by the first power and repeated a plurality of times.

2. The plasma generation method as claimed in claim 1, wherein the step of decreasing the power supplied to the plasma generator by the second power is repeated until the power supplied to the plasma generator reaches the predetermined power.

3. The plasma generation method as claimed in claim 1, wherein the step of decreasing the power supplied to the plasma generator by the first power is performed upon detecting that the power supplied to the plasma generator is the normal power, and
wherein a third power decreased by the first power from the normal power is set at a power that does not extinguish the plasma.

4. The plasma generation method as claimed in claim 3, wherein the third power is set at 1000 W or higher.

5. The plasma processing method as claimed in claim 4, further comprising:
decreasing the power supplied to the plasma generator by a fourth power that is smaller than the first power and greater than the second power between the steps of decreasing the power supplied to the plasma generator by the first power and decreasing the power supplied to the plasma generator by the second power.

6. The plasma generation method as claimed in claim 1, wherein the step of generating the plasma of the ignition gas comprises generating the plasma of a gas that does not contain oxygen.

7. The plasma generation method as claimed in claim 1, further comprising:
stopping supply of the ignition gas between the steps of generating the plasma of the ignition gas and decreasing the power supplied to the plasma generator by the first power.

8. A plasma processing method, comprising steps of:
placing a substrate on a susceptor provided in a process chamber, the substrate having an undercoat film other than an oxide film formed thereon;
generating plasma of an ignition gas by supplying a normal power to a plasma generator and supplying the ignition gas into the process chamber;
decreasing power supplied to the plasma generator by a first power that is smaller than the normal power;
stopping supply of the ignition gas into the process chamber;
decreasing the power supplied to the plasma generator by a second power that is smaller than the first power after decreasing the power supplied to the plasma generator by the first power;
repeating the decreasing the power supplied to the plasma generator by the second power a plurality of times;
adsorbing a silicon-containing gas on the substrate by supplying the silicon-containing gas into the process chamber;
depositing a molecular layer of a silicon oxide on the substrate by supplying an oxidation gas into the process chamber, converting the oxidation gas to plasma by the plasma generator to which a power smaller than the normal power is supplied, and oxidizing the silicon-containing gas adsorbed on the substrate.

9. The plasma processing method as claimed in claim 8,
wherein the undercoat film is a nitride film, and
wherein the ignition gas is a nitrogen-containing gas.

10. A plasma processing apparatus, comprising:
a process chamber;
a susceptor provided in the process chamber to support a substrate on a top surface thereon;
a first process gas nozzle to supply a silicon-containing gas to the susceptor;
a second process gas nozzle to supply, to the susceptor, an oxidation gas and an ignition gas that is used to ignite plasma and does not contain an oxidant;
a plasma generator configured to activate the oxidation gas supplied from the second process gas nozzle;
a radio frequency power source configured to supply radio frequency power to the plasma generator; and
a controller configured to control the second process gas nozzle and the radio frequency power source and to perform the following steps of:
supplying the ignition gas from the second process gas nozzle;
generating plasma of the ignition gas by causing the radio frequency power source to supply a normal power to the plasma generator;
decreasing a power supplied to the plasma generator by a first power by controlling the radio frequency power source;
decreasing the power supplied to the plasma generator by a second power that is smaller than the first power by controlling the radio frequency poser source; and
repeating the decreasing the power supplied to the plasma generator by the second power a plurality of times until the power supplied to the plasma generator decreases to a predetermined power.
wherein a source gas supply area for supplying the source gas to the substrate, a reaction gas supply area for supplying the reaction gas to the substrate, and a plasma processing area for performing the plasma process on the film are provided above the susceptor and along the circumferential direction, and
the steps of supplying the source gas to the substrate, supplying the reaction gas to the substrate and performing the plasma process on the film are performed by rotating the susceptor a plurality of times to cause the substrate to pass through the source gas supply area, the reaction gas supply area and the plasma processing area the plurality of times.
